(19) United States
(12) Patent Application Publication
(10) Pub. No.: US 2008/0296705 A1
(43) Pub. Date: Dec. 4, 2008

(54) GATE AND MANUFACTURING METHOD OF GATE MATERIAL

(75) Inventor: Jhy-Jyi Sze, Hsinchu City (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/754,847

(22) Filed: May 29, 2007

(51) Int. Cl. H01L 29/94; H01L 21/3205

(52) U.S. Cl. 257/412; 438/592; 257/E21.294; 257/E29.234

(57) ABSTRACT

A gate including a conductive buffer layer and a conductive layer is provided. The conductive buffer layer is disposed on a gate dielectric layer, and the average grain size of the conductive buffer layer is less than 100 nm. The conductive layer is disposed on the conductive buffer layer, and the average grain size of the conductive layer is greater than or equal to 100 nm. The disposition of the conductive buffer layer reduces the undesired effect caused by noise and dark current to the performance of the device.

### BACKGROUND OF THE INVENTION

1. Field of the Invention

The present invention generally relates to a semiconductor device and a manufacturing method thereof, in particular, to a gate and a manufacturing method of a gate material.

2. Description of Related Art

Presently, metal oxide semiconductor (MOS) has been broadly applied to logic devices, memory devices, and image sensors etc.

For example, complementary metal oxide semiconductor (CMOS) image sensor is broadly adopted by various image processing devices such as handheld color cameras, security monitoring black/white cameras, digital cameras, fax machines, and medical sensors etc due to its advantages of high stability, high sensibility, low operation voltage, low power consumption, high impedance, and immunity to high magnetic field etc.

However, such a CMOS may produce relatively large dark current and other noises so that it cannot be applied in an environment with low illumination and cannot be exposed for long time. The large dark current makes it very difficult to distinguish brightness and darkness and accordingly reduces the dynamic range. In addition, the white defect caused by unbalanced and large dark current produces signals greater than a normal signal. Thus, a technique for reducing dark current is required.

On the other hand, the gate of MOS is usually fabricated with N- or P-doped polysilicon in order to improve the conductivity of the gate. However, the implantation of dopant causes the grain size of the re-crystallized polysilicon material through a thermal process to increase, and which changes the original physical characteristics of the polysilicon gate and increases the opportunity of charge accumulation, and accordingly, the undesired effect of dark current and noises becomes more serious and the performance of the device is further reduced.

### SUMMARY OF THE INVENTION

Accordingly, the present invention is directed to a gate which has a conductive buffer layer for reducing the noise and dark current in a device applying the gate and accordingly improving the performance of the device.

The present invention is directed to a manufacturing method of a gate material, wherein a conductive buffer layer whose average grain size is less than 100 nm is formed to reduce the noise and dark current in a device.

The present invention provides a gate disposed on a gate dielectric layer. The gate includes a conductive buffer layer and a conductive layer. The conductive buffer layer is disposed on the, gate dielectric layer, and the average grain size of the conductive buffer layer is less than 100 nm. The conductive layer is disposed on the conductive buffer layer, and the average grain size of the conductive layer is greater than or equal to 100 nm.

According to an embodiment of the present invention, the material of the conductive buffer layer and the conductive layer includes polysilicon.

According to an embodiment of the present invention, the material of the conductive layer includes doped polysilicon.

According to an embodiment of the present invention, the material of the conductive layer includes N-doped polysilicon.

According to an embodiment of the present invention, the gate is suitable for a complementary metal oxide semiconductor (CMOS).

According to an embodiment of the present invention, the gate is suitable for a CMOS image sensor (CIS).

According to an embodiment of the present invention, the thickness of the conductive buffer layer is about 500 Å, and the thickness of the conductive layer is about 1500 Å.

The present invention provides a manufacturing method of a gate material, and the manufacturing method includes forming a conductive buffer layer, wherein the average grain size of the conductive buffer layer is less than 100 nm.

According to an embodiment of the present invention, in the manufacturing method of a gate material, the material of the conductive buffer layer includes polysilicon.

According to an embodiment of the present invention, in the manufacturing method of a gate material, the formation method of the conductive buffer layer includes chemical vapour deposition (CVD), wherein the reactive gas is SiH₄, the gas flow is between 0.15 slm and 0.35 slm, the reaction pressure is between 30 mTorr and 60 mTorr, and the reaction temperature is between 680° C. and 705° C.

According to an embodiment of the present invention, the manufacturing method of a gate material further includes performing a dopant implantation process after the conductive buffer layer is formed, and the average grain size at the bottom of the conductive buffer layer is maintained less than 100 nm.

According to an embodiment of the present invention, the manufacturing method of a gate material further includes forming a conductive layer on the conductive buffer layer after the conductive buffer layer is formed.

According to an embodiment of the present invention, in the manufacturing method of a gate material, the average grain size of the conductive layer is greater than or equal to 100 nm.

According to an embodiment of the present invention, in the manufacturing method of a gate material, the material of the conductive buffer layer and the conductive layer includes polysilicon, and the formation method of the conductive buffer layer and the conductive layer includes CVD.

According to an embodiment of the present invention, in the CVD process, the gas flow of the silicon-containing gas for forming the conductive buffer layer is smaller than that of the silicon-containing gas for forming the conductive layer.

According to an embodiment of the present invention, in the CVD process, the gas flow of the silicon-containing gas for forming the conductive buffer layer is between 0.15 slm and 0.35 slm, and the gas flow of the silicon-containing gas for forming the conductive layer is between 0.25 slm and 0.45 slm.

According to an embodiment of the present invention, in the manufacturing method of a gate material, the temperature of the CVD process is between 680° C. and 705° C.

According to an embodiment of the present invention, in the manufacturing method of a gate material, the pressure of the CVD process is between 30 mTorr and 60 mTorr.

According to an embodiment of the present invention, the manufacturing method of a gate material further includes performing a dopant implantation process after the conductive layer is formed.

According to an embodiment of the present invention, the manufacturing method of a gate material further includes performing an annealing process after the dopant implantation process is performed, wherein the average grain size of the conductive buffer layer is maintained less than 100 nm after the annealing process.

In the present invention, a conductive buffer layer having small average grain size is formed on a gate dielectric layer for being the material of the gate, so that the noise and dark current in a device are effectively reduced and accordingly the performance of the device is improved.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a metal oxide semiconductor (MOS) according to an embodiment of the present invention.

FIGS. 2A-2C are cross-sectional views illustrating a manufacturing flow of a gate material according to an embodiment of the present invention.

FIGS. 3A-3C are cross-sectional views illustrating a manufacturing flow of a gate material according to another embodiment of the present invention.

FIG. 4 illustrates the relationships between the thickness of a conductive buffer layer and noise and dark current according to an embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

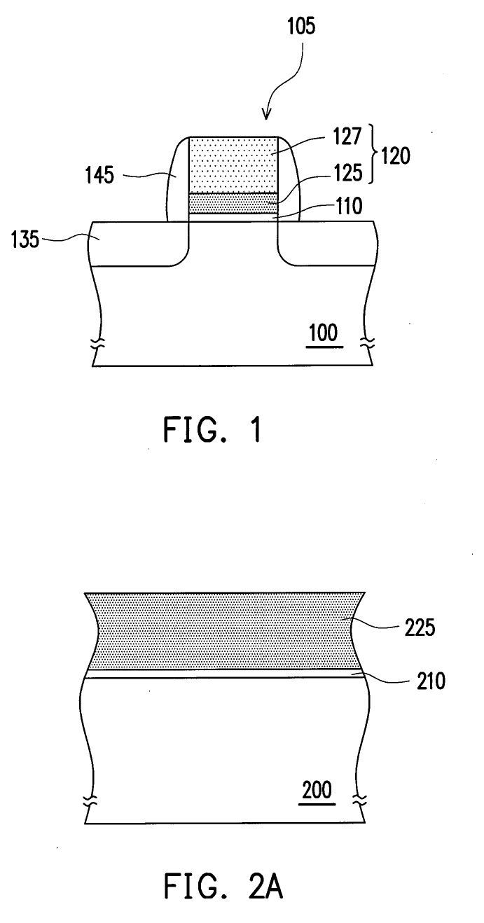

FIG. 1 is a cross-sectional view of a metal oxide semiconductor (MOS) according to an embodiment of the present invention.

Referring to FIG. 1, a MOS is illustrated and explained in the present embodiment as an example; however, the application of the gate provided by the present invention is not limited thereto. Referring to FIG. 1, the MOS 105 is disposed on a substrate 100 and includes a gate dielectric layer 110, a gate 120, and a doped region 135.

The gate dielectric layer 110 is disposed on the substrate 100, and the material thereof may be a dielectric material such as silicon oxide. The gate 120 is disposed on the gate dielectric layer 110 and which includes a conductive buffer layer 125 disposed on the gate dielectric layer 110 and a conductive layer 127 disposed on the conductive buffer layer 125. The material of the conductive buffer layer 125 and the conductive layer 127 may be polysilicon. The conductive buffer layer 125 may be a uniform polysilicon crystal with its average grain size less than 100 nm, and the average grain size of the conductive layer 127 is greater than or equal to 100 nm. The thickness of the conductive buffer layer 125 may be greater than 300 Å, and the thicknesses of the gate 120 and the conductive layer 127 may be adjusted according to the requirement of the device.

Since the average grain size of the conductive buffer layer 125 disposed between the gate dielectric layer 110 and the conductive layer 127 is less than 100 nm, the stress in the polysilicon crystal lattice can be relatively released so as to reduce the opportunity of charge accumulation. Accordingly, the purpose of reducing noise and dark current can be achieved.

In an embodiment of the present invention, the thickness of the conductive buffer layer 125 may be 500 Å, and the thickness of the conductive layer 127 may be 1500 Å. The material of the conductive layer 127 may be polysilicon doped with N-dopant such as arsenic and phosphor or P-dopant such as boron according to design requirement. The conductive buffer layer 125 may also contain some dopant due to the dopant implantation process; however, this small quantity of dopant does not affect the grain size of the conductive buffer layer 125 so that the conductive buffer layer 125 retains its characteristic of small grain size. It should be noted that the conductive buffer layer 125 is still a uniform polysilicon formed by poly-crystalline but not amorphous silicon even though the grain size thereof is less than 100 nm.

The doped region 135 is further disposed in the substrate 100 at both sides of the gate 120 to serve as the source/drain of the MOS 105. A spacer 145 may be disposed on the sidewall of the gate 120. The doped region 135 may be a heavily P- or N-doped region. The material of the spacer 145 may be a dielectric material such as silicon oxide.

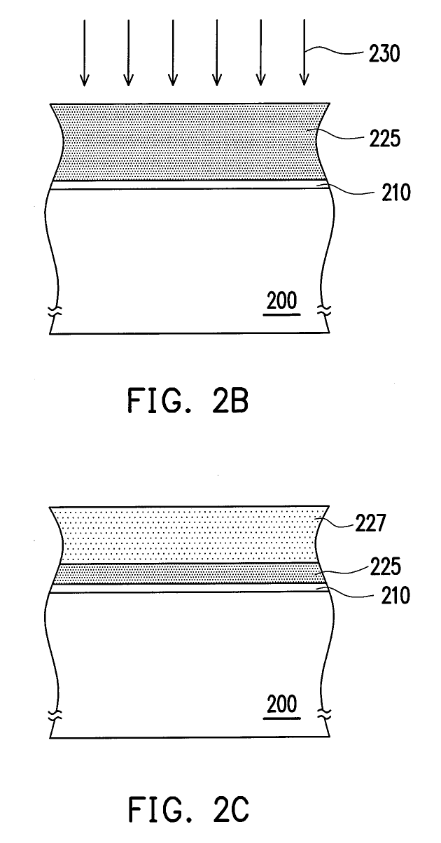

FIGS. 2A-2C are cross-sectional views illustrating a manufacturing flow of a gate material according to an embodiment of the present invention.

Referring to FIG. 2A, a gate dielectric layer 210 has been formed on a substrate 200, wherein the gate dielectric layer 210 may be formed through thermal oxidation or chemical vapor deposition (CVD), and the material thereof may be silicon oxide. According to this manufacturing method, a conductive buffer layer 220 may be formed on the gate dielectric layer 210. The material of the conductive buffer layer 220 may be polysilicon, and the formation method thereof may be CVD. According to an embodiment of the present invention, in the CVD process, the reactive gas used may be SiH₄, the gas flow may be between 0.15 slm and 0.35 slm, the reaction pressure may be between 30 mTorr and 60 mTorr, and the reaction temperature may be between 680° C. and 705° C., wherein H₂ and Dichlorosilane (DCS) may also be added in the CVD process. However, the reactive gas may also be other silicon-containing gas such as disilane, DCS, or TEOS etc. For example, in another embodiment of the present invention, SiH₄ is used as the reactive gas, the gas flow is 0.19 slm, the reaction pressure is 45 mTorr, and the reaction temperature is 698° C. A pre-deposition process may be further performed with silicon-containing gas of 0.06 slm before the conductive buffer layer 220 is deposited.

Referring to FIG. 2B, after forming the conductive buffer layer 220, a dopant implantation process 230 may be further performed to implant N-dopant such as arsenic and phosphor or P-dopant such as boron in the polysilicon material according to the design requirement of the device. The polysilicon material becomes amorphous silicon without fixed structure due to the implanted dopant. In an embodiment of the present embodiment, the thickness of the conductive buffer layer 220 may be 2000 Å, and the dopant implantation process 230 may be to implant dopant into the upper portion of the conductive buffer layer 220 of about 1500 Å. The implanted depth and thickness of the dopant may be controlled by adjusting the implanting power and current according to the design requirement of the device.

Referring to FIG. 2C, a thermal annealing process is then performed to re-crystallize the doped amorphous silicon. Since the upper portion of the conductive buffer layer 220 has been doped with dopant, the grain size of the re-crystallized polysilicon material is greater than the original 100 nm and accordingly the upper portion of the conductive buffer layer 220 becomes the conductive layer 227. Since the lower conductive buffer layer 225 is not implanted with dopant (or only implanted with a small quantity of dopant), it retains its original grain size (less than 100 nm). The conductive layer 227 and the conductive buffer layer 225 form a gate material having two different grain sizes, wherein the average grain size of the upper conductive layer 227 is greater than or equal to 100 nm, while the average grain size of the lower conductive buffer layer 225 is less than 100 nm. In an embodiment of the present invention, the thickness of the conductive buffer layer 225 may be greater than 300 Å, and the thickness of the conductive layer 227 may be less than 1700 Å. For example, the thickness of the conductive buffer layer 225 may be 500 Å, and the thickness of the conductive layer 227 may be 1500 Å. The subsequent processes for defining a gate pattern and manufacturing a MOS are well-known to those skilled in the art therefore will not be described herein.

It should be mentioned that even though in the embodiment described above, the dopant implantation process 230 is performed after the conductive buffer layer 225 has been formed, in another embodiment of the present invention, an in-situ dopant implantation process may also be performed after a certain thickness of the conductive buffer layer 220 has been deposited, namely, during the CVD process, but before the conductive buffer layer 220 is completed. The in-situ dopant implantation process also maintains the grain size at the bottom of the conductive buffer layer 220 to be less than

Since there is a conductive buffer layer 225 having smaller grain size between the gate dielectric layer 210 and the conductive layer 227 having larger grain size, the possibility of charge accumulation is reduced, so that the undesired effect of noise and dark current is reduced and accordingly the performance of the device is improved. Regarding a CIS, due to the reduction of the undesired effect of noise and dark current, the signal charge of the image sensor can be more sensitive, and accordingly the image quality of the display device can be improved.

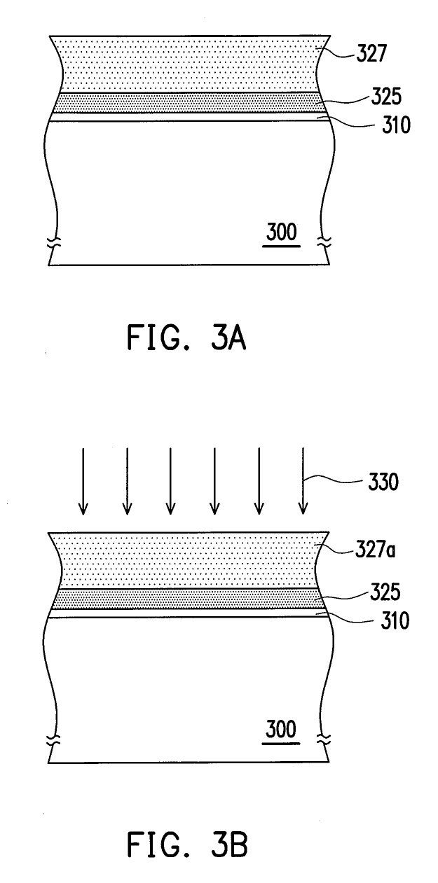

FIGS. 3A-3C are cross-sectional views illustrating a manufacturing flow of a gate material according to another embodiment of the present invention.

Referring to FIG. 3A, according to this method, the gate material is formed above the gate dielectric layer 310 on the substrate 300. The gate material may be polysilicon, and the formation method thereof may be CVD. In the CVD process, the temperature may be between 680° C. and 705° C., the reaction pressure in the chamber may be between 30 mTorr and 60 mTorr, and the reactive gas used may be SiH₄. At first, the gas flow of SiH₄ may be controlled between 0.15 slm and 0.35 slm to form a conductive buffer layer 325. Since the gas flow of SiH₄ is small, the average grain size of the conductive buffer layer 325 may be less than 100 nm. In an embodiment of the present invention, the thickness of the conductive buffer layer 325 may be greater than 300 Å, for example, 500 Å.

After that, the CVD process is continued, and the gas flow of SiH₄ is increased to between 0.25 slm and 0.45 slm to form a conductive layer 327. Here the grain size of the polysilicon increases, for example, to be greater than or equal to 100 nm, and accordingly the deposition speed thereof also increases. In an embodiment of the present invention, the thickness of the conductive layer 327 may be about 1500 Å.

Besides SiH₄, H₂ or DCS or both of the two may also be added in the reactive gas in foregoing CVD process as adjustment of process factors. However, besides SiH₄, the silicon-containing gas used as the reactive gas may also be disilane, DCS, or TEOS etc. according to the requirement of the process.

In an embodiment of the present invention, in the CVD process for forming the gate material, SiH₄ along with H₂ and DCS may be used as the reactive gas, and the reaction temperature is controlled to be 698° C., the reaction pressure is controlled to be below 45 mTorr. At first, the gas flow of SiH₄ is controlled to be 0.19 slm to form a conductive buffer layer 325 of about 500 Å, and then the gas flow of SiH₄ is increased to 0.27 slm to form a conductive layer 327 of about 1500 Å.

Referring to FIG. 3B, after the CVD process, a dopant implantation process 330 is further performed to implant N-dopant such as arsenic and phosphor or P-dopant such as boron in the polysilicon material. The polysilicon material becomes amorphous silicon without fixed structure due to the implanted dopant. The profile depth of the implanted dopant may be controlled at about 1500 Å, namely, most dopant is implanted into the conductive layer 327a of greater grain size, and much less dopant is implanted in the conductive buffer layer 325. However, the implanted depth of dopant is not restricted to the thickness of the conductive layer 327a, instead, dopant may also be implanted into part of the conductive buffer layer 325 as long as at least 300 Å of conductive buffer layer 325 is remained nearly undoped, wherein the implanted depth and thickness of the dopant are determined according to the requirement of the process.

After that, referring to FIG. 3C, a thermal annealing process is performed to re-crystallize the doped amorphous silicon. Since the conductive layer 327a has been doped, the grain size of the re-crystallized polysilicon is further increased. The bottom part of the conductive buffer layer 325 is not implanted with dopant (or only doped with a small quantity of dopant), thus, it retains its original average grain size (less than 100 nm).

In other words, there is always a conductive buffer layer 325 having its grain size less than 100 nm between the gate dielectric layer 310 and the conductive layer 327a. This conductive buffer layer 325 can reduce the opportunity of charge accumulation due to its small grain size, so that the undesired effect of noise and dark current can be reduced and accordingly the performance of the device subsequently formed can be improved.

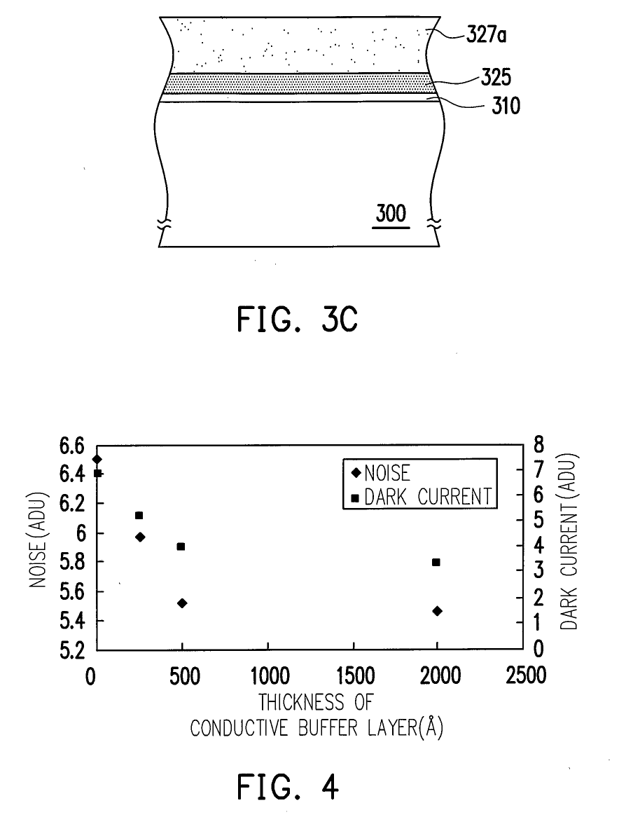

FIG. 4 illustrates the relationships between the thickness of a conductive buffer layer and noise and dark current according to an embodiment of the present invention.

Referring to FIG. 4, with different thickness of the conductive buffer layer, the analogy digit unit (ADU) of noise is denoted with “♦”, and the ADU of the dark current is denoted with “▪”. In the present embodiment, the material of the gate is polysilicon, and the gate includes a conductive buffer layer having its grain size less than 100 nm and a conductive layer having its grain size greater than or equal to 100 nm, and these two layers form the gate of total thickness about 2000 Å. In other words, if the thickness of the conductive buffer layer is 250 Å, then the thickness of the conductive layer is 1750 Å; and if the thickness of the conductive buffer layer is 2000 Å, then the thickness of the conductive layer is 0 Å, and so on. The upper ¾ portion of the gate, namely, about 1500 Å, of the gate is doped with N-dopant such as arsenic or phosphor. In the present embodiment, the changes of ADUs of the noise and dark current are observed by changing the thickness of the conductive buffer layer of the gate.

As shown in FIG. 4, when the thickness of the conductive buffer layer is 0 Å, the noise is 6.5, the dark current is 6.88, and along with the increase in the thickness of the conductive buffer layer, the ADUs of the noise and dark current decrease accordingly. In particular, the ADUs of the noise and dark current decrease dramatically when the thickness of the conductive buffer layer is increased from 0 Å to 500 Å, wherein the noise decreases from 6.5 to 5.51 and the dark current decreases from 6.88 to 3.98. Foregoing result shows that the conductive buffer layer does reduce the noise and dark current.

On the other hand, when the conductive buffer layer is increased from 500 Å to 2000 Å, the decreases of the noise and dark current are slowed down. When the conductive buffer layer is 2000 Å (i.e. the entire gate serves as the conductive buffer layer), the noise is 5.43 and the dark current is 3.35 and which are only a little bit lower than the noise and dark current when the thickness of the conductive buffer layer is 500 Å.

It should be mentioned here that in the present embodiment, the N-dopant in the polysilicon material of the gate is mostly distributed in the upper 1500 Å of the gate. It can be understood from the embodiment described above that the grain size of the heavily doped polysilicon is increased and does not retains its original grain size which is less than 100 nm. This is one of the reasons that the decrements of the noise and dark current are slowed down when the thickness of the conductive buffer layer is increased from 500 Å to 2000 Å. In other words, those skilled in the art may flexibly adjust the factors such as the thickness of the gate, the thickness of the conductive buffer layer, and the profile depth of the implanted dopant according to the requirement of the device to design a most suitable device pattern.

In summary, a gate and a manufacturing method of a gate material are provided by the present invention, wherein a conductive buffer layer having its average grain size less than 100 nm is adopted as the material of a gate for reducing the undesired effect of noise and dark current and improving the performance of the device. Accordingly, the sensitivity of signal charge is improved and the quality of the electronic apparatus is improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A gate, disposed on a gate dielectric layer, the gate comprising:
a conductive buffer layer, disposed on the gate dielectric layer, the average grain size of the conductive buffer layer being less than 100 nm; and
a conductive layer, disposed on the conductive buffer layer, the average grain size of the conductive layer being greater than or equal to 100 nm.

2. The gate according to claim 1, wherein the material of the conductive buffer layer and the conductive layer comprises polysilicon.

3. The gate according to claim 1, wherein the material of the conductive layer comprises doped polysilicon.

4. The gate according to claim 1, wherein the material of the conductive layer comprises N-doped polysilicon.

5. The gate according to claim 1, wherein the gate is suitable for a complementary metal oxide semiconductor (CMOS).

6. The gate according to claim 1, wherein the gate is suitable for a CMOS image sensor (CIS).

7. The gate according to claim 1, wherein the thickness of the conductive buffer layer is greater than or equal to 300Å.

8-21. (canceled)
